(19) United States
(12) Patent Application Publication
(10) Pub. No.: US 2019/0227658 A1
(43) Pub. Date: Jul. 25, 2019

(54) TOUCH DRIVING CIRCUIT, TOUCH COMPONENT, AND DISPLAY TOUCH DEVICE

(71) Applicant: Wuhan China Star Optoelectronics Semiconductor Display Technology Co., Ltd., Wuhan (CN)

(72) Inventors: Dan LIN, Shenzhen (CN); Minlun LIU, Shenzhen (CN); Qibing DAI, Shenzhen (CN)

(21) Appl. No.: 16/034,851

(22) Filed: Jul. 13, 2018

Related U.S. Application Data
(63) Continuation of application No. PCT/CN2018/076340, filed on Feb. 11, 2018.

(30) Foreign Application Priority Data
Jan. 23, 2018 (CN) 201810064389.4

(51) Int. Cl. G06F 3/041; G09G 3/3208; G06F 3/044; H01L 27/32

(52) U.S. Cl. CPC G06F 3/0412; G09G 3/3208; H01L 27/323; G06F 3/044; G06F 3/0416

(57) ABSTRACT

The present application provides a touch driving circuit for driving an OLED touch panel. The touch driving circuit includes a touch chip, and a regulation voltage generating circuit. The touch chip includes a first voltage generating circuit to generate first voltage signals, and the first voltage signals are provided to an emitter electrode of the OLED touch panel. The regulation voltage generating circuit generates a regulation voltage having the same voltage polarity as the cathode voltage loaded at the cathode in the OLED touch panel. The regulation voltage is provided to the emitter electrode. With the above arrangement, the amount of charges flowing from the emitter electrode to the cathode and the amount of charges flowing from the receiver electrode to the cathode are respectively reduced, thereby improving the touch performance. The present application further provides a touch component and a display touch device.

### CROSS REFERENCE TO RELATED APPLICATIONS

This application is a continuing application of PCT Patent Application No. PCT/CN2018/076340, entitled “TOUCH DRIVING CIRCUIT, TOUCH COMPONENT, TOUCH DRIVING METHOD, AND DISPLAY TOUCH DEVICE”, filed on Feb. 11, 2018, which claims priority to Chinese Patent Application No. 201810064389.4, filed on Jan. 23, 2018, both of which are hereby incorporated in its entireties by reference.

### BACKGROUND

### 1. Technical Field

This application relates to the field of touch technology, and in particular relates to a touch driving circuit, a touch component, and a display touch device.

### 2. Description of Related Art

An AMOLED display technology is a very competitive display technology in the future, including an OLED display panel, and a touch panel on an upper surface of the OLED display panel. The touch panel includes a plurality of touch electrodes. In order to make the AMOLED display thinner and lighter, the touch electrodes are directly mounted on cathodes of a package layer, to achieve integration of a touch display. However, when the touch electrodes are closed to the cathodes, the coupling capacitance between the touch electrodes and the cathodes may increase, so that the amount of charges flowing from the touch electrodes to the cathodes may be excessive. As a result, when the human finger touches the OLED display panel, the amount of change in the capacitance of the touch electrode is too small, thereby affecting the touch performance.

### SUMMARY

The present disclosure relates to a touch driving circuit capable of reducing the amount of charges flowing from the touch electrode to the cathode.

For purposes of implementing the present application, the present application provides the following technical solutions:

In a first aspect, the present application provides a touch driving circuit for driving an OLED touch panel. The touch driving circuit includes a touch chip and a regulation voltage generating circuit. The touch chip includes a first voltage generating circuit. The first voltage generating circuit generates first voltage signals, and the first voltage signals is provided to an emitter electrode of the OLED touch panel. The regulation voltage generating circuit generates a regulation voltage. The regulation voltage having the same voltage polarity as a cathode voltage loaded at the cathode in the OLED touch panel, and the regulation voltage is provided to the emitter electrode.

In a first possible implementation of the first aspect, the regulation voltage is the same as the cathode voltage loaded at the cathode.

In a second possible implementation of the first aspect, the touch chip includes an adder circuit. The cathode is electrically connected to the adder circuit and the cathode voltage is used as the regulation voltage.

In a second aspect, the present application provides a touch component. The touch component includes a touch driving circuit and a touch display panel. The touch driving circuit includes a touch chip and a regulation voltage generating circuit. The touch display panel includes a cathode, an emitter electrode, and a receiver electrode. The touch chip includes a first voltage generating circuit. A first coupling capacitor is formed between the emitter electrode and the receiver electrode, a second coupling capacitor is formed between the emitter electrode and the cathode, and a third coupling capacitor is formed between the receiver electrode and the cathode. The first voltage generating circuit outputs first voltage signals to the emitter electrode to charge the first coupling capacitor, the second coupling capacitor, and the third coupling capacitor. The regulation voltage generating circuit generates a regulation voltage that is provided to the emitter electrode, and the regulation voltage having the same voltage polarity as a cathode voltage loaded at the cathode.

In a first possible implementation of the second aspect, the regulation voltage is the same as the cathode voltage loaded at the cathode.

In a second possible implementation of the second aspect, the touch chip includes an adder circuit, the cathode is electrically connected to the adder circuit, and the cathode voltage is used as the adjusting voltage.

In a third aspect, the present application further provides a touch display device comprising a touch driving circuit implemented in any implementation of the first aspect.

The beneficial effects of the present application:

The touch driving circuit provided in the present application includes the regulation voltage generating circuit to generate the regulation voltage.

The regulation voltage having the same voltage polarity as the cathode voltage, and the regulation voltage is provided to the emitter electrode. Therefore, most of the cathode voltage are cancelled out, and the amount of charges flowing from the emitter electrode and the receiver electrode to the cathode is reduced, thereby improving the touch performance.

### BRIEF DESCRIPTION OF THE DRAWINGS

In order to more clearly illustrate the embodiments of the present disclosure or prior art solutions, the drawings used in the description of the embodiments or prior art will be briefly described below. The drawings are merely some embodiments of the present disclosure, and those skilled in the art can also obtain other drawings based on these drawings without any creative work.

FIG. 1 is a schematic structural diagram of an OLED touch panel according to an embodiment of the present application;

FIG. 2 is a schematic diagram showing the relationship between the touch component and the touch chip in an embodiment of the present application;

FIG. 3 is a schematic diagram of a relationship between a touch component and a touch chip according to another embodiment of the present application:

FIG. 4 is a schematic diagram showing the relationship between the touch component and the touch chip electrically connected according to another embodiment of the present application;

FIG. 5 is a schematic structural diagram of a touch driving circuit according to an embodiment of the present application;

FIG. 6 is a schematic diagram of a voltage signal according to an embodiment:

FIG. 7 is a schematic diagram of the voltage signal after the voltage signal of FIG. 6 is loaded with the regulation voltage.

### DETAILED DESCRIPTION

Following embodiments of the invention will now be described in detail hereinafter with reference to the accompanying drawings.

The touch driving circuit provided by this application can be applied to display touch devices such as smart phones, tablet computers, mobile assistants, conference presentation devices, and the like.

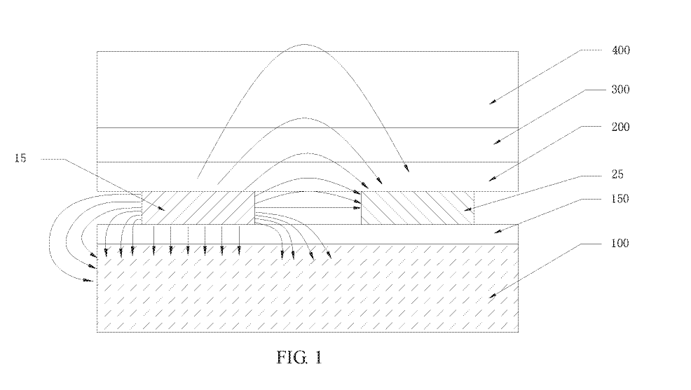

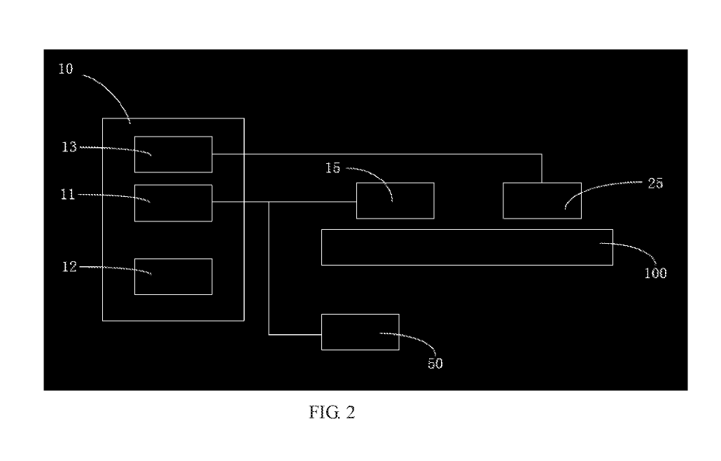

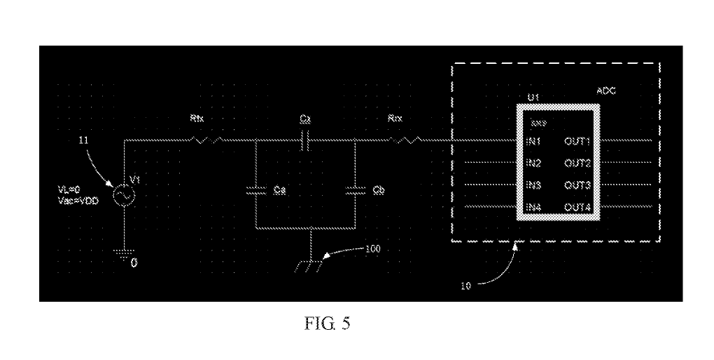

With reference to FIGS. 1, 2, and 5. FIG. 1 is a schematic structural diagram of an OLED touch panel according to an embodiment of the present application. FIG. 2 is a schematic diagram illustrating a relationship between a touch element and a touch control chip according to an embodiment of the present application. FIG. 5 is a schematic structural diagram of a touch driving circuit according to an embodiment of the present application. The OLED touch panel includes a cathode 100, an encapsulating layer 150, a touch electrode (an emitter electrode 15 and a receiver electrode 25), a polarizer 200, an OCA adhesive layer 300, and a cover plate 400 stacked in sequence. The emitter electrode 15 and the receiver electrode 25 are covered on the cathode 100 in a grid shape to form a touch structure. When the emitter electrode 15 receiving the voltage signal, a first coupling capacitor Cx is formed between the emitter electrode 15 and the receiver electrode 25. The first coupling capacitor Cx forms an electric field between the emitter electrode 15 and the receiver electrode 25. Electric field lines are shown by the arrow lines in FIG. 1. When the human finger touches the surface of the cover plate 400, since the human body is equivalent to the ground, some of the electrode lines generated by the emitter electrode 15 are grounded by the human finger and fails to reach the receiver electrode 25. A phenomenon that the amount of electric charge received by the receiver electrode 25 decreases may be caused, and the capacitance of the first coupling capacitance Cx may be changed. A signal processing module 13 of the touch chip 10 calculates a position where the amount of charges of the receiver electrode 25 is reduced, thereby achieving the effect of the touch.

With reference to FIGS. 2 and 5, the emitter electrode 15 and the receiver electrode 25 are in close proximity to the cathode 100, and the distance thereof is far smaller than a distance between the emitter electrode 15 and the receiver electrode 25. The emitter electrode 15, the receiver electrode 25, and the cathode 100 are both metal materials, a second coupling capacitor Ca is formed between the emitter electrode 15 and the cathode 100, and a third coupling capacitor Cb is formed between the receiver electrode 25 and the cathode 100. A capacitor formula is shown as C=εS/4×kd, wherein ε is a constant, S is a directly facing area of the capacitor plates, d is the distance of the capacitor plates, and k is the electrostatic force constant. A directly facing area S between the emitter electrode 15 and the cathode 100 and a directly facing area S between the receiver electrode 25 and the cathode 100 are respectively generally larger than a directly facing area S between the emitter electrode 15 and the receiver. A distance d between the emitter electrode 15 and the cathode 100 and a distance d between the receiver electrode 25 and the cathode 100 are respectively much smaller than a distance between the emitter electrode 15 and the receiver electrode 25. Therefore, the second coupling capacitor Ca and the third coupling capacitor Cb will much larger than the first coupling capacitor Cx. The cathode 100 may have a cathode voltage due to the display driving circuit. The presence of the cathode voltage makes an voltage between the second coupling capacitor Ca and the third coupling capacitor Cb become more larger than that when the voltage of the cathode voltage is zero. It will cause more electric field lines absorbed by the cathode 100. That is, the amount of electric charges flowing from the emitter electrode 15 to the cathode 100 and the amount of electric charges flowing from the and the receiving electrode 25 to the cathode 100 are more, which greatly affects the touch effect.

With reference to FIG. 2, a touch driving circuit provided by a first embodiment of the present application is configured to drive the OLED touch panel. The touch driving circuit includes a touch chip 10 and a regulation voltage generating circuit 50. The touch chip 10 includes a first voltage generating circuit 11 for generating first voltage signals. The first voltage signals is provided to the emitter electrode 15 of the OLED touch panel. The regulation voltage generating circuit 50 generates an regulation voltage. The regulation voltage has the same voltage polarity as the cathode voltage loaded at the cathode 100 in the OLED touch panel. The regulation voltage is provided to the emission electrode 15.

The touch driving circuit provided in the present application includes the regulation voltage generating circuit 50 to generate the regulation voltage. The regulation voltage having the same voltage polarity as the cathode voltage, and the regulation voltage is provided to the emitter electrode. Therefore, most the cathode voltage are cancelled out, and the amount of charges flowing from the emitter electrode to the cathode and the amount of charges flowing from the receiver electrode to the cathode are respectively reduced. Since the capacitances of the second coupling capacitor Ca and the capacitances of the third coupling capacitor Cb are stationary, when the first voltage generating circuit 11 charges the second coupling capacitor Ca and the third coupling capacitor Cb, the voltage between the second coupling capacitor Ca and the third coupling of the capacitor Cb is reduced, so that the amount of charges flowing from the emitter electrode 15 and the receiver electrode 25 to the cathode 100 is reduced, thereby improving the touch performance.

The regulation voltage generating circuit 11 may be provided individually, or the regulation voltage generating circuit 11 may be provided in a driving circuit of an OLED (not shown). The present application is not limited specifically an internal structure of the regulation voltage generating circuit 11.

In one embodiment, the regulation voltage is the same as the cathode voltage loaded at the cathode 100. Therefore, the cathode voltage is completely cancelled, and the voltage between the emitter electrode 15 and the cathode 100 is zero. Then, the amount of charges flowing from the emitter electrode 15 to the cathode 100 and the amount of charges flowing from the receiver electrode 25 to the cathode 100 are respectively minimized, and further improving the touch performance.

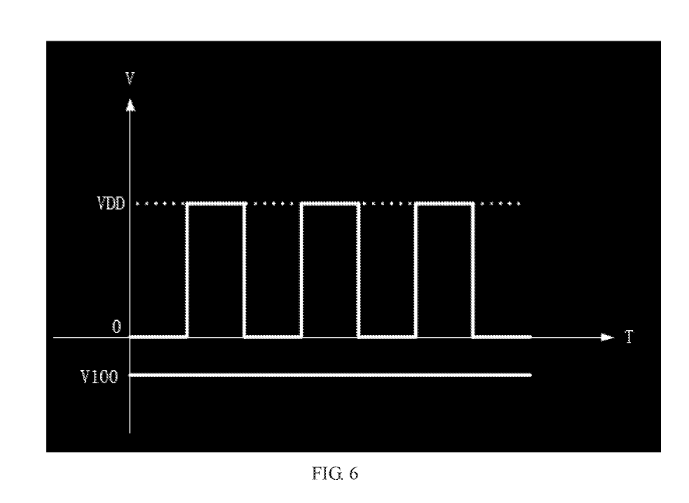

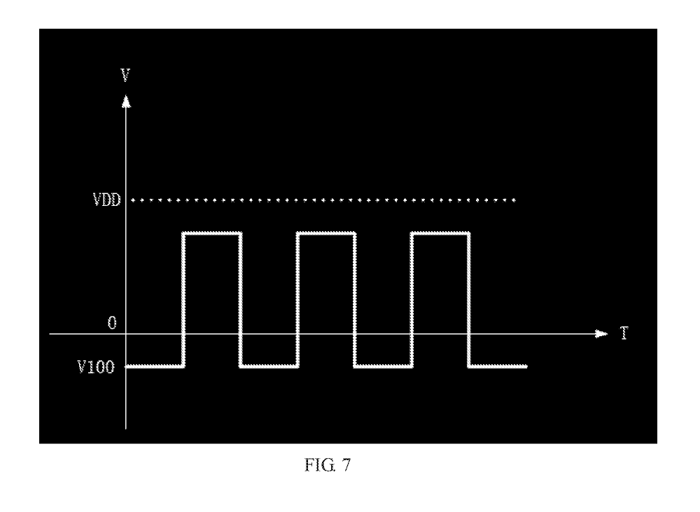

FIG. 6 is a schematic diagram of one embodiment of a voltage signal. The cathode voltage loaded at the cathode 100 is a negative voltage, and the negative voltage is generated by the driving circuit of the OLED when the OLED is driven by the driving circuit to emit light. The regulation voltage V100 generated by the regulation voltage generating circuit 50 is also a negative voltage. For example, the cathode voltage of the cathode 100 is generally −1V˜−3V. and the first voltage generated by the first voltage generation circuit 11 may be a square wave signal. Such that, the OLED touch panel is driven in an intermittent pulse driving. When the first voltage is at a low level, the OLED touch panel is rested. When the first voltage is at a high level, the OLED touch panel is driven. The resource allocation of the touch chip 10 can be optimized, the energy consumption can be reduced, and the touch effect does not be affected. A high level voltage of the square wave signal is VDD, and the low level voltage of the square wave signal is 0. When the touch electrode 15 is loaded the regulation voltage V100, please refer to FIG. 7.

FIG. 7 is a schematic diagram of the voltage signal after the voltage signal of FIG. 6 is loaded with the regulation voltage. A low level voltage of the touch electrode 15 is V100, and a high level voltage of the touch electrode 15 is VDD−V100. For example, the cathode voltage loaded at the cathode 100 is −2V, the high level voltage VDD of the square wave signal is 6V, the low level voltage of the square wave signal is 0V, and the regulation voltage V100 is −1V. When the square wave signal is loaded the regulation voltage V100 with −1V. the low level voltage of the square wave signal received by the touch electrode 15 is −1V. and the high level voltage of the square wave signal is 6V−1V=5V. When square wave signal is the low level voltage, a voltage between two terminals of the second coupling capacitor Ca is 1V. When the square wave signal is the high level voltage, the voltage between two terminals of the second coupling capacitor Ca is 5V−(−1V)=6V. When the square wave signal does not the regulation voltage V100, the original high level voltage of the square wave signal is 6V, and the original voltage between two terminals of the second coupling capacitor Ca is 6V−(−2V)=8V. Therefore, the voltage between two terminals of the second coupling capacitor Ca is reduced. The difference of a voltage between two terminals of the third coupling capacitor Cb when the square wave signal is loaded the regulation voltage V100 may be obtain according to the same principle. Therefore, it is omitted.

With reference to FIG. 5, a first voltage generation circuit 11 may be a circuit connected to an alternating current power (e.g. the power source from the electric socket). The touch chip 10 further comprises an amplifier (AMP) and an analog to digital converter (ADC). In general, the change of charges received by the receiver electrode 25 is few. The amplifier amplifies the change of the charges received by the receiver electrode 25, and the signal processing module 13 of the touch chip 10 can process the amplified change of the charges received by the receiver electrode 25. The ADC converts signals outputted by the amplifier from analog signals to digital signals that can be processed by the signal processing module 13 of the touch chip 10.

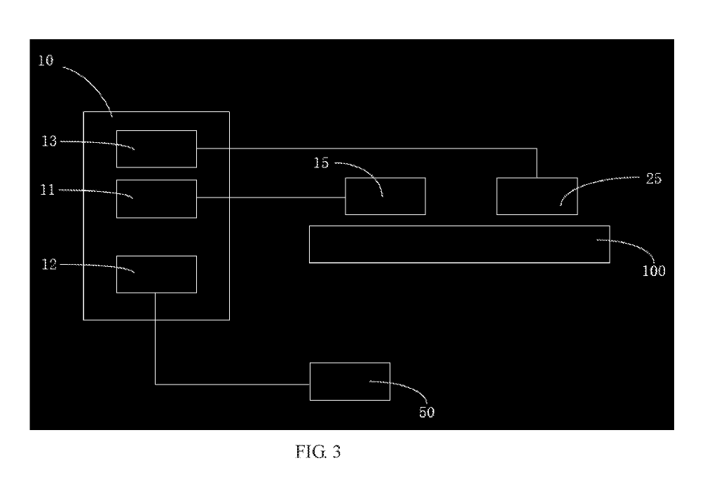

FIG. 3 is a schematic diagram of a relationship between a touch component and the touch chip 10, which is substantially the same as the first embodiment. The difference from the first embodiment is that the touch control chip 10 includes an adder circuit 12. The regulation voltage generated by the regulation voltage generating circuit 50 is provided to the adder circuit 12, and the adder circuit 12 loads the regulation voltage to the first voltage generating circuit 11. Therefore, the voltage signal generated by the first voltage generating circuit 11 is a superposition signal of the first voltage signals and the regulation voltage. The superposition signal is provided to the driving electrode 15. Then, the amount of charges flowing from the emitter electrode 15 to the cathode 100 and the amount of charges flowing from the receiver electrode 25 to the cathode 100 are respectively reduced, thereby improving the touch performance.

The function of the adder circuit 12 loads a voltage on another voltage. In this embodiment, the regulation voltage is added on the first voltage signals of the touch chip 10. This application does not limit the specific structure of the adder circuit 12 as long as the adder circuit 12 can performance the above function.

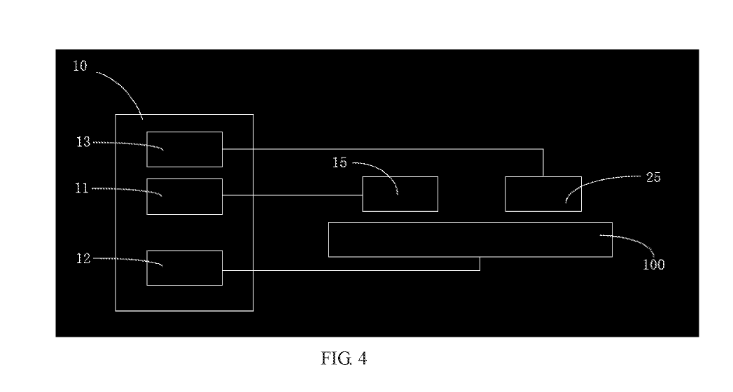

In one embodiment, with reference to FIG. 4, FIG. 4 is a schematic diagram of the electrical connection relationship between the touch component and the touch chip, which is substantially the same as the first embodiment. The difference from the first embodiment is that the touch control chip 10 includes an adder circuit 12. The cathode 100 is electrically connected to the adder circuit 12, and the cathode voltage is used as the regulation voltage. The adder circuit 12 adds the cathode voltage to the first voltage signals. Therefore, a voltage between the touch electrode 15 and the cathode 100 becomes zero. Then, the amount of charges flowing from the emitter electrode 15 to the cathode 100 and the amount of charges flowing from the receiver electrode 25 to the cathode 100 are respectively reduced, thereby improving the touch performance.

The adder circuit 12 in this embodiment functions to add the regulation voltage signal to the first voltage signals of the touch control chip 10.

In one embodiment, a charge process of the touch driving circuit to charge the first coupling capacitor Cx, the second coupling capacitor Ca, and the third coupling capacitor Cb is the integration process. A voltage between two terminals of the first coupling capacitor Cx, a voltage between two terminals of the second coupling capacitor Ca. and a voltage between two terminals of the third coupling capacitor Cb respectively change with time, until the first coupling capacitor Cx, the second coupling capacitor Ca, and the third coupling capacitor Cb are charged saturation.

Specifically a cathode voltage value on the capacitor is V0, an ending voltage when a capacitor is fully charged is Vu, and a voltage value on the capacitor at time t is Vt. A rated voltage of the touch chip 10 is E, a resistance of a circuit is R, and a capacitance of the capacitor is C.

Then, Vt=V0+(Vu−V0)*[1−exp(−t/RC)]

When V0=0, the charging limit Vu=E,

Charge amount Q=E*C(1−e\hat{ }(−t/RC))

It should be appreciated that C is a total capacitance of the circuit. In the present embodiment, the total amount of charges of the circuit Q=Qx+Qa+Qb. Wherein Qx is the amount of charges of the first coupling capacitor Cx, Qa is the amount of charges of the second coupling capacitor Ca, and Qb is the amount of charges of the third coupling capacitor Qb. Then Qa=E*Ca(1−e\hat{ }(−t/RCx)). Qx and Qb can be obtained with a similar formula.

In one embodiment, the emitter electrode 15 includes a first impedance Rtx, and the receiver electrode 25 includes a second impedance Rrx. When the first coupling capacitor Cx, the second coupling capacitor Ca, and the third coupling capacitor Cb are fully charged, a voltage of the first coupling capacitor Cx, a voltage of the second coupling capacitor Ca, and a voltage of the third coupling capacitor Cb are respectively less than the high level voltage of the first voltage signals (the square wave signal) generated by the first voltage generating circuit 11.

Since the impedance will result in the loss of a part of the voltage, when the capacitor is charged to t=3RC, the voltage of the capacitor=0.95E is considered to be saturated. That is, Q=0.95E*C. The high level voltage of the first voltage signals (the square wave signal) generated by the first voltage generating circuit 11 is the rated voltage E. Because of the loss, the voltage of the capacitor is smaller than the voltage output by the touch chip 10.

With reference to FIGS. 1 to 7, the present application further provides a touch component including a touch driving circuit and a touch display panel. The touch driving circuit includes a touch chip 10 and a regulation voltage generation circuit 50. The touch display panel includes a cathode 100, an emitter electrode 15, and a receiver electrode 25. The touch sensor chip 10 includes a first voltage generating circuit 11. A first coupling capacitor Cx is formed between the emitter electrode 15 and the receiver electrode 25, a second coupling capacitor Ca is formed between the emitter electrode 15 and the cathode 100, and a third coupling capacitor Cb is formed between the receiver electrode 25 and the cathode 100. The first voltage generating circuit 11 outputs first voltage signals to the emitter electrode 15 to charge the first coupling capacitor Cx, the second coupling capacitor Ca, and the third coupling capacitor Cb. The regulation voltage generating circuit 50 generates a regulation voltage. The regulation voltage is provided to the emitter electrode 15, and the regulation voltage has the same voltage polarity as the cathode voltage loaded at the cathode 100.

In one embodiment, the regulation voltage is the same as the cathode voltage loaded at the cathode 100.

In one embodiment, the touch chip 10 includes an adder circuit 12, the cathode 100 is electrically connected to the adder circuit 12, and the cathode voltage is used as the regulation voltage.

With reference to FIGS. 1 to 7, the present application further provides a touch driving method including the following steps:

configuring a touch configuration chip 10 and a regulation voltage generating circuit 50; wherein the touch chip 10 includes a first voltage generating circuit 11, the first voltage generating circuit 11 generates first voltage signals and provides the first voltage signals to an emitter electrode 15 of the OLED touch panel;

wherein regulation voltage generating circuit 50 generates an regulation voltage, the regulation voltage has the same voltage polarity as the cathode voltage loaded at the cathode 100 in the OLED touch panel, and the regulation voltage is provided to the emitting electrode 15.

In one embodiment, the regulation voltage is set to be the same as the cathode voltage loaded at the cathode 100.

In an embodiment, the touch chip 10 includes an adder circuit 12. The adder circuit 12 is electrically connected to the cathode 100, and the cathode voltage is used as the regulation voltage.

The above description is merely the embodiments in the present disclosure, the claim is not limited to the description thereby. The equivalent structure or changing of the process of the content of the description and the figures, or to implement to other technical field directly or indirectly should be included in the claim.

What is claimed is:

1. A touch driving circuit for driving an Organic light emitting diode (OLED) touch panel, comprising:
a touch chip and an regulation voltage generating circuit:
wherein the touch chip comprises a first voltage generation circuit for generating first voltage signals, and the first voltage signals is provided to an emitter electrode of the OLED touch panel; wherein the regulation voltage generating circuit generates an regulation voltage, a polarity of the regulation voltage is the same with a polarity of a cathode voltage loaded at a cathode in the OLED touch panel, and the regulation voltage is provided to the emitter electrode.

2. The touch driving circuit as claimed in claim 1, wherein the regulation voltage is equal to the cathode voltage loaded at the cathode.

3. The touch driver circuit as claimed in claim 1, wherein the touch chip further comprises an adder circuit electrically connected to the cathode, and the cathode voltage operates as the regulation voltage.

4. A touch component, comprising:
a touch driving circuit and a touch display panel;
wherein the touch driving circuit comprises a touch chip and a regulation voltage generating circuit; wherein the touch display panel comprises a cathode, an emitter electrode, and a receiver electrode; wherein the touch chip comprises a first voltage generating circuit; wherein a first coupling capacitor is formed between the emitter electrode and the receiver electrode, a second coupling capacitor is formed between the emitter electrode and the cathode, and a third coupling capacitor is formed between the receiver electrode and the cathode; wherein the first voltage generating circuit outputs first voltage signals to the emitter electrode to charge the first coupling capacitor, the second coupling capacitor, and the third coupling capacitor; wherein the regulation voltage generating circuit generates a regulation voltage being provided to the emitter electrode, and a polarity of the regulation voltage is the same with a polarity of the cathode voltage loaded at the cathode.

5. The touch component as claimed in claim 4, wherein the regulation voltage is equal to the cathode voltage.

6. The touch component as claimed in claim 4, wherein the touch chip further comprises an adder circuit, the adder circuit is electrically connected to the cathode, and the cathode voltage operates as the regulation voltage.

7. A display touch device, comprising:
a touch driver circuit comprising a touch chip and a regulation voltage generating circuit;
wherein the touch chip comprises a first voltage generating circuit for generating first voltage signals, and the first voltage signals are provided to an emitter electrode of an OLED touch panel;
wherein the regulation voltage generating circuit generates an regulation voltage, a polarity of the regulation voltage is the same with a polarity of the cathode voltage loaded at a cathode in the OLED touch panel, and the regulation voltage is provided to the emitter electrode.

8. The display touch device as claimed in claim 7, wherein the regulation voltage is equal to the cathode voltage loaded at the cathode.

9. The display touch device as claimed in claim 7, wherein the touch chip further comprises an adder circuit, the adder circuit is electrically connected to the cathode, and the cathode voltage operates the regulation voltage.
